(19) United States
(12) Patent Application Publication
(10) Pub. No.: US 2026/0177601 A1
(43) Pub. Date: Jun. 25, 2026

(54) Transformer Winding Short Circuit Fault Detection Method, System, Storage Medium and Equipment

(71) Applicant: Yunnan Power Grid Co., Ltd. Electric Power Research Institute, Kunming (CN)

(72) Inventors: Qingjun PENG, Kunming (CN); Dexu ZOU, Kunming (CN); Desheng CHU, Kunming (CN); Fangrong ZHOU, Kunming (CN); Shan WANG, Kunming (CN); Zhihu HONG, Kunming (CN); Zewen YANG, Kunming (CN); Xin WANG, Kunming (CN); Yuepei ZOU, Kunming (CN)

(21) Appl. No.: 19/381,378

(22) Filed: Nov. 6, 2025

Related U.S. Application Data
(63) Continuation of application No. PCT/CN2025/115652, filed on Aug. 19, 2025.

(30) Foreign Application Priority Data
Dec. 24, 2024 (CN) 202411916038.3

(51) Int. Cl. G01R 31/08; G01R 31/62; G01R 33/02

(52) U.S. Cl. CPC G01R 31/088; G01R 31/081; G01R 31/62; G01R 33/02

(57) ABSTRACT

The embodiment of the present invention discloses a transformer winding short circuit fault detection method, comprising: acquiring magnetic flux leakage data between transformer windings; determining a short circuit fault area according to the magnetic flux leakage data; establishing a transformer finite element model; and simulating the transformer finite element model based on the short circuit fault area, so as to obtain a short circuit database. The present invention achieves precise detection on transformer winding short circuit faults, not only improving the accuracy and efficiency of fault detection.

### CROSS-REFERENCE TO RELATED APPLICATIONS

The present application is a continuation of International Application No. PCT/CN2025/115652, filed on Aug. 19, 2025, and claims priority to Chinese Patent Application No. 202411916038.3, filed on Dec. 24, 2024, the entire disclosure of which is incorporated herein by reference.

### BACKGROUND

Transformers are indispensable and crucial equipment in the power system, responsible for the transmission and distribution of electrical energy. However, during long-term operation, transformers may be affected by various factors, such as over-voltage, over-current, environmental factors, and equipment aging, resulting in various faults.

Short circuit faults are a common and highly dangerous type of failure. Short circuit faults can cause the internal windings of the transformer to overheat, leading to serious consequences such as damage of insulation materials, fires and explosions, causing a significant impact on the safe and stable operation of the power system.

At present, the diagnostic methods for transformer short circuit faults mainly include two approaches, namely manual inspection and local monitoring devices. The manual inspection method relies on the experience and skills of inspectors, which has problems such as strong subjectivity, low efficiency, prone to misjudgment or missed detection. While the local monitoring devices can monitor the state of transformer in specific areas, but cannot comprehensively cover all areas of the transformers, which may lead to missed detections or false detections, and cannot accurately determine the fault location, thus failing to meet the requirement of rapid diagnosis.

### SUMMARY

Based on this, it is necessary to disclose a transformer winding short circuit fault detection method in response to the problems.

A transformer winding short circuit fault detection method, including the following steps:
acquiring magnetic flux leakage data between transformer windings;
determining a short circuit fault area according to the magnetic flux leakage data;
establishing a transformer finite element model;
simulating the transformer finite element model based on the short circuit fault area, so as to obtain a short circuit database; and
acquiring magnetic flux leakage data between transformer windings in real time and determining a short circuit fault location of transformer windings according to the short circuit database.

In the scheme above, the acquiring magnetic flux leakage data between transformer windings, specifically includes:
evenly arranging a plurality of magnetic sensors along the axial direction of the transformer windings, so as to form a sensor group; and
measuring magnetic leakage fluxes at all locations between transformer windings according to the sensor group, so as to acquire magnetic flux leakage data between transformer windings.

In the scheme above, after acquiring magnetic flux leakage data between transformer windings, the method further includes:
a step of pre-processing acquired magnetic flux leakage data, wherein the step of pre-processing comprises denoising, filtering, calibration and standardizing.

In the scheme above, after acquiring magnetic flux leakage data between transformer windings, the method further includes:
carrying out mode recognition on pre-processed magnetic flux leakage data, so as to judge operation states of a transformer, wherein the operation states of the transformer comprise a normal stable operation state, an on-position state and a winding short circuit state.

In the scheme above, the determining the short circuit fault area according to the magnetic flux leakage data, specifically includes:
when determining that the operation state of the transformer is the winding short circuit state, arranging the pre-processed magnetic flux leakage data according to amplitude of variation, so as to obtain a magnetic flux leakage variation sequence table; and
determining a short circuit fault area according to the magnetic flux leakage variation sequence table.

In the scheme above, the simulating the transformer finite element model based on the short circuit fault area, so as to obtain the short circuit database, specifically includes:
setting short circuit conditions for short circuit locations in the short circuit fault area, and carrying out transient study thereon;
acquiring magnetic flux leakage traversal results of the transformer finite element model, wherein the magnetic flux leakage traversal results comprise port current waveforms, voltage waveforms and winding magnetic flux leakage data; and
establishing the short circuit database according to the port current waveforms, voltage waveforms and winding magnetic flux leakage data.

In the scheme above, the acquiring magnetic flux leakage data between transformer windings in real time and determining the short circuit fault location of transformer windings according to the short circuit database, specifically includes:
comparing the magnetic flux leakage data of the sensor with the magnetic flux leakage traversal results;
determining corresponding fault situations according to a minimum difference; and
comparing current on line side and voltage recording data at the short circuit fault with current and voltage data obtained from the finite element model, so as to determine a short circuit fault spot.

The present application further includes a transformer winding short circuit fault detection system, including: a magnetic flux leakage data acquiring unit, a short circuit fault determining unit, a simulation model establishing unit and a fault location determining unit,
wherein the magnetic flux leakage data acquiring unit is used for acquiring magnetic flux leakage data between transformer windings;
the short circuit fault determining unit is used for determining a short circuit fault area according to the magnetic flux leakage data;
the simulation model establishing unit is used for establishing a transformer finite element model, and simulating the transformer finite element model based on the short circuit fault area, so as to obtain a short circuit database; and
the fault location determining unit is used for acquiring magnetic flux leakage data between transformer windings in real time and determining a short circuit fault location of transformer windings according to the short circuit database.

The present application further includes a computer readable storage medium, with computer programs stored thereon, wherein the following steps are achieved by a processor when the computer programs are executed by the processor:
acquiring magnetic flux leakage data between transformer windings;
determining a short circuit fault area according to the magnetic flux leakage data;
establishing a transformer finite element model;
simulating the transformer finite element model based on the short circuit fault area, so as to obtain a short circuit database; and
acquiring magnetic flux leakage data between transformer windings in real time and determining a short circuit fault location of transformer windings according to the short circuit database.

The present application further includes a computer device, including a memory and a processor, wherein the memory is used for storing computer programs; and the following steps are achieved when the computer programs are executed by the processor:
acquiring magnetic flux leakage data between transformer windings;
determining a short circuit fault area according to the magnetic flux leakage data;
establishing a transformer finite element model;
simulating the transformer finite element model based on the short circuit fault area, so as to obtain a short circuit database; and
acquiring magnetic flux leakage data between transformer windings in real time and determining a short circuit fault location of transformer windings according to the short circuit database.

Adoption of the embodiment of the present invention has the following beneficial effects: first acquiring magnetic flux leakage data between transformer windings; determining the short circuit fault area according to the magnetic flux leakage data; establishing the transformer finite element model; simulating the transformer finite element model based on the short circuit fault area, so as to obtain the short circuit database; and acquiring magnetic flux leakage data between transformer windings in real time and determining the short circuit fault location of transformer windings according to the short circuit database. According to the present invention, by acquiring magnetic flux leakage data, determining the short circuit fault area, establishing the transformer finite element model, simulating to obtain the short circuit database, and performing real-time fault positioning, precise detection on transformer winding short circuit faults is achieved, and by adopting the method, not only is the accuracy and efficiency of fault detection improved, but also a strong guarantee is provided for safe operation of the transformer.

### BRIEF DESCRIPTION OF DRAWINGS

In order to describe the technical solutions in the embodiments of the present invention or in the prior art more clearly, a brief description of the accompanying drawings required for describing the embodiments or the prior art will be provided below. Obviously, the accompanying drawings in the following description show merely some embodiments of the present invention. Those of ordinary skill in the art can also derive other accompanying drawings from these accompanying drawings without making creative efforts.

In the drawings:

FIG. 1 is a process diagram of a transformer winding short circuit fault detection method of one embodiment.

### DETAILED DESCRIPTION OF THE EMBODIMENTS

The technical solutions in the embodiments of the present invention are clearly and completely described below in conjunction with the accompanying drawings in the embodiments of the present invention. Apparently, the embodiments described are only a part rather than all of the embodiments of the present invention. Based on the embodiments of the present invention, all other embodiments obtained by those of ordinary skill in the art without making any creative efforts fall within the scope of protection of the present invention.

In the following description, a large number of specific details are provided to offer a more thorough understanding of the present invention. However, it is obvious to those skilled in the art that the present invention can be implemented without one or more of these details. In other embodiments, in order to avoid confusion with the present invention, some technical features known in the art are not described. It should be understood that the present invention can be implemented in different forms and should not be interpreted as being limited to the embodiments presented here. Conversely, providing these embodiments will make the present disclosure complete and thorough, and will fully convey the scope of the present invention to those skilled in the art.

The purpose of using terms herein is merely for describing the specific embodiments and is not for limiting the present invention. When used herein, the singular forms “one”, “an” and “said/the” are also intended to include the plural forms, unless the context clearly indicates otherwise. It should also be understood that the terms “consisting of” and/or “including” indicate the presence of the specified features, integers, steps, operations, components and/or parts used in the specification, but do not exclude the existence or addition of one or more other features, integers, steps, operations, components, parts and/or groups. When used herein, the term “and/or” includes any and all combinations of the listed items.

To facilitate understanding, relevant terms involved in the present application are explained below first.

Magnetic flux leakage data, refers to magnetic flux data that a part of magnetic fluxes cannot completely penetrate through an iron core, but leaking out around the iron core because of magnetic circuit saturation, structural defects in windings, or external factors during the operation process of a transformer. These data can be collected by magnetic sensors installed around transformer windings.

Transformer winding, one of the core components of a transformer, which is responsible for transmission and conversion of electrical power. A winding is generally formed by copper wires or aluminum wires wound together, and is insulated in transformer oil or other insulating materials.

Transient study, refers to study on state variation of a system within a short time, particularly focusing on the dynamic response process of the system in transient disturbance or motivation.

To fully understand the present invention, the detailed structure will be presented in the following description in order to explain the technical solution disclosed by the present invention. The optional embodiments of the present invention are described in detail as follows. However, apart from these detailed descriptions, the present invention can also have other implementation methods.

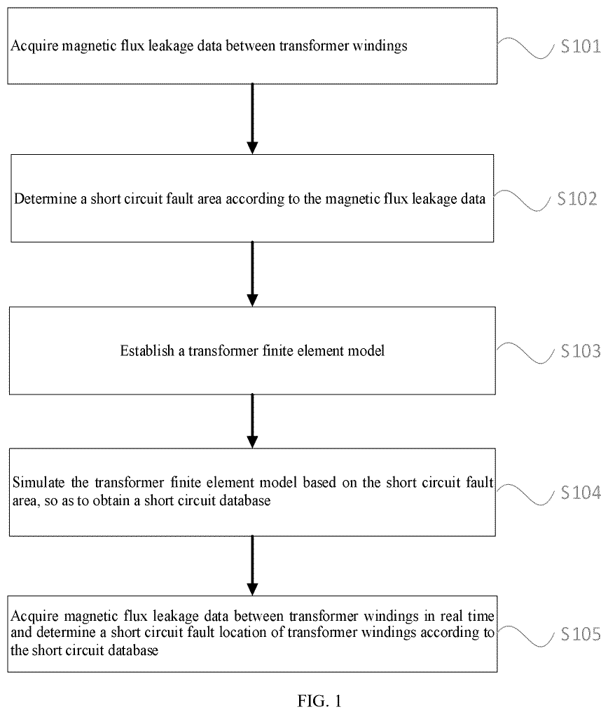

As shown in FIG. 1, in one embodiment, a transformer winding short circuit fault detection method is provided. The transformer winding short circuit fault detection method includes step S101 to step S105, as follows:

S101, acquiring magnetic flux leakage data between transformer windings.

This step is the start point of the detection method. Through the magnetic sensor group, amplitudes and directions of magnetic flux leakages between transformer windings can be measured, and amplitudes and directions of magnetic flux leakages are related to factors such as the current, loops and geometrical shapes of windings. Therefore, the health state of the windings can be reflected, basic data can be provided for subsequent fault diagnosis, and basis can be provided for judging fault areas and establishing simulation models.

In some embodiments, the acquiring magnetic flux leakage data between transformer windings, specifically includes:
evenly arranging a plurality of magnetic sensors along the axial direction of the transformer windings, so as to form a sensor group; and
measuring magnetic leakage fluxes at all locations between transformer windings according to the sensor group, so as to acquire magnetic flux leakage data between transformer windings.

Preferably, the location of a single sensor is designed according to expected precision of magnetic flux leakage measurement, and then single sensors are respectively responsible for magnetic flux leakage monitoring on corresponding coil pancakes. Multiple sensors are evenly arranged in the axial direction of the transformer windings, so as to form a sensor group to correctly measure magnetic leakage fluxes at all locations between the windings.

Furthermore, a non-magnetic bracket or fixture is used to fix the sensors, so as to ensure stable positions thereof in the operation process, and prevent measurement data distortion caused by vibration or other external factors.

In some embodiments, after acquiring magnetic flux leakage data between transformer windings, the method further includes:
a step of pre-processing acquired magnetic flux leakage data, wherein the step of pre-processing includes denoising, filtering, calibration and standardizing.

During the operation process of the transformer, a data acquisition system is started, to record magnetic flux leakage data acquired from the sensors in real time, and the acquired magnetic flux leakage data are subjected to necessary pre-processing, so as to improve the reliability and accuracy of data.

In some embodiments, after acquiring magnetic flux leakage data between transformer windings, the method further includes:
carrying out mode recognition on pre-processed magnetic flux leakage data, so as to judge operation states of the transformer, wherein the operation states of the transformer includes a normal stable operation state, an on-position state and a winding short circuit state.

Specifically, magnetic flux leakage data can be of three modes:
during normal and stable operation of the transformer, the magnetic flux leakage valid value is generally maintained unchanged;
when the transformer is at an on-position state, data of all sensors vary significantly; and
when a transformer winding is in short circuit, magnetic flux leakage data near the winding is in short circuit vary significantly, and magnetic flux leakage at other locations varies faintly.

By analyzing variation trends and modes of the magnetic flux leakage data, the operation state of the transformer is judged, and in case the winding is in short circuit, the magnetic flux leakage data are in the pattern of mode (3).

S102, determining a short circuit fault area according to the magnetic flux leakage data.

By analyzing magnetic flux leakage data, areas with abnormality of magnetic flux leakage (such as variations of intensity, distribution and the like) can be recognized, thereby primarily judging potential areas of short circuit faults. For example, short circuit faults can result in increase of magnetic leakage fluxes in one area, then the diagnosis range can be narrowed, the diagnosis efficiency can be improved, necessary inspection on the whole transformer can be avoided, and the efficiency and accuracy of subsequent steps can be improved.

In some embodiments, the determining the short circuit fault area according to the magnetic flux leakage data, specifically includes:
when determining that the operation state of the transformer is the winding short circuit state, arranging the pre-processed magnetic flux leakage data according to amplitude of variation, so as to obtain the magnetic flux leakage variation sequence table; and

determining the short circuit fault area according to the magnetic flux leakage variation sequence table.

S103, establishing a transformer finite element model.

According to the physical structure and electrical parameters of the transformer, a precise finite element model is established. The finite element model is capable of simulating the magnetic field distribution of the transformer winding, then distribution of magnetic flux leakages at different fault states can be calculated, to provide a basis for subsequent simulation and establishment of short circuit database.

Specifically, the establishing a multi-section winding finite element model adaptive to transformer winding short circuit fault analysis in COMSOL software based on actual transformer parameters, specifically includes: dividing the transformer finite element model into three parts, namely an iron core, a winding and an oil tank, wherein the iron core is of a structure designed in the pattern of stacked silicon steel sheets; the winding is divided into multiple pancake units according to actual coil pancake structures, and the pancake units are established in a single conductor helical structure; and the oil tank is simplified into a cuboid structure.

S104, simulating the transformer finite element model based on the short circuit fault area, so as to obtain a short circuit database.

By simulating the finite element model, magnetic flux leakage data at different short circuit fault locations can be obtained, the short circuit database is established, the database contains magnetic flux leakage characteristics at different fault states, corresponding relationships between the short circuit faults and magnetic flux leakage data are established for subsequent fault diagnosis, and then a reference can be provided for actual fault diagnosis. By comparing magnetic flux leakage data acquired in real time with database data, database data most matched with actual fault situations can be recognized, and thus the fault location can be determined.

In some embodiments, the simulating the transformer finite element model based on the short circuit fault area, so as to obtain the short circuit database, specifically includes:
setting short circuit conditions for short circuit locations in the short circuit fault area, and carrying out transient study thereon;
acquiring magnetic flux leakage traversal results of the transformer finite element model, wherein the magnetic flux leakage traversal results comprise port current waveforms, voltage waveforms and winding magnetic flux leakage data; and
establishing the short circuit database according to the port current waveforms, voltage waveforms and winding magnetic flux leakage data.

S105, acquiring magnetic flux leakage data between transformer windings in real time and determining a short circuit fault location of transformer windings according to the short circuit database.

During the operation process of the transformer, magnetic flux leakage data between windings are acquired in real time, magnetic flux leakage data acquired in real time are compared and analyzed with data in the short circuit database to determine specific locations of short circuit faults, then real-time accurate detection on transformer winding short circuit faults is achieved, and promptness and effectiveness of fault processing are improved.

By comparing the magnetic flux leakage data acquired in real time with short circuit database data, a matching index can be calculated, such as distance and similarity, and a fault location corresponding to the database data with the highest matching is the most possible fault location.

In some embodiments, the acquiring magnetic flux leakage data between transformer windings in real time and determining a short circuit fault location of transformer windings according to the short circuit database, specifically includes:
comparing the magnetic flux leakage data of the sensor with the magnetic flux leakage traversal results;
determining corresponding fault situations according to a minimum difference; and
comparing current on line side and voltage recording data at the short circuit fault with current and voltage data obtained from the finite element model, so as to determine a short circuit fault spot.

Specifically, the port current waveform, the voltage data and the magnetic flux leakage data are taken as judgment bases, port current and voltage data can be acquired through fault recording, and the magnetic flux leakage data are provided by the magnetic sensor group.

First, based on the traversal results obtained through simulation, the magnetic flux leakage data of the sensor are compared with magnetic flux leakage traversal results of the finite element model, and a fault situation with the minimum difference is selected for next judgment. Further, the current on line side and the voltage recording data of the short circuit fault are compared with current and voltage data obtained by the finite element model. If waveforms of the two are of high consistency, the short circuit point is taken as the correct fault point, or else, data of other fault points in the area are continuously compared, until a short circuit fault spot is determined.

To sum up, the present invention utilizes the relationship between electromagnetic coupling, magnetic flux leakage data are monitored by the magnetic sensor group in real time, areas of the transformer are completely covered, possible location of short circuit fault spots are monitored, then the short circuit locations can be accurately judged, and uncertainty of subjective judgment in conventional methods is avoided, being significant for safe operation and fault analysis of the transformer.

The present application further includes a transformer winding short circuit fault detection system, including: a magnetic flux leakage data acquiring unit, a short circuit fault determining unit, a simulation model establishing unit and a fault location determining unit,
wherein the magnetic flux leakage data acquiring unit is used for acquiring magnetic flux leakage data between transformer windings;
the short circuit fault determining unit is used for determining a short circuit fault area according to the magnetic flux leakage data;
the simulation model establishing unit is used for establishing a transformer finite element model, and simulating the transformer finite element model based on the short circuit fault area, so as to obtain a short circuit database; and
the fault location determining unit is used for acquiring magnetic flux leakage data between transformer windings in real time and determining a short circuit fault location of transformer windings according to the short circuit database.

The present application further includes a computer readable storage medium, with computer programs stored thereon, wherein the following steps are achieved by a processor when the computer programs are executed by the processor:
acquiring magnetic flux leakage data between transformer windings;
determining a short circuit fault area according to the magnetic flux leakage data;
establishing a transformer finite element model;
simulating the transformer finite element model based on the short circuit fault area, so as to obtain a short circuit database; and
acquiring magnetic flux leakage data between transformer windings in real time and determining a short circuit fault location of transformer windings according to the short circuit database.

The present application further includes a computer device, including a memory and a processor, wherein the memory is used for storing computer programs; and the following steps are achieved when the computer programs are executed by the processor:
acquiring magnetic flux leakage data between transformer windings;
determining a short circuit fault area according to the magnetic flux leakage data;
establishing a transformer finite element model;
simulating the transformer finite element model based on the short circuit fault area, so as to obtain a short circuit database; and
acquiring magnetic flux leakage data between transformer windings in real time and determining a short circuit fault location of transformer windings according to the short circuit database.

Those of ordinary skill in the art can understand that all or part of the processes in the methods of the embodiments can be accomplished by instructing relevant hardware through a computer program. The program can be stored in a non-volatile computer-readable storage medium. When executed, the program may include the processes of the embodiments of the methods. Any reference to the memory, the storage, the database, or other media which are used in the examples provided in the present invention may include a non-volatile memory and/or a volatile memory. Non-volatile memory may include read-only memory (ROM), programmable ROM (PROM), electrically programmable ROM (EPROM), electrically erasable programmable ROM (EEPROM), or flash memory. Volatile memory can include random access memory (RAM) or external cache memory. As an illustration rather than a limitation, RAM can be available in various forms, such as static RAM (SRAM), dynamic RAM (DRAM), synchronous DRAM (SDRAM), double data rate SDRAM (DDRSDRAM), enhanced SDRAM (ESDRAM), synchronous link (Synchlink) DRAM (SLDRAM), memory bus (Rambus) direct RAM (RDRAM), direct memory bus dynamic RAM (DRDRAM), and memory bus dynamic RAM (RDRAM), etc.

Various technical features of the above embodiments can be arbitrarily combined. For brevity of description, all possible combinations of various technical features in the above embodiments are not described. However, as long as there is no contradiction between the combinations of these technical features, they should all be considered as a scope recited in the present specification.

The embodiments described above represent only several implementation modes of the present application, and the description is specific and detailed, but should not be construed as limiting the scope of present application accordingly. It should be noted that for those of ordinary skill in the art, without departing from the conception of the present application, modifications and improvements can also be made, which all fall within the protection scope of the present application. The disclosure above is merely optimal embodiments of the present invention, and cannot be used to limit the scope of rights of the present invention. Therefore, any equivalent changes made based on the claims of the present invention still fall within the scope covered by the present invention.

What is claimed is:

1. A transformer winding short circuit fault detection method, comprising:
acquiring magnetic flux leakage data between transformer windings;
determining a short circuit fault area according to the magnetic flux leakage data;
establishing a transformer finite element model;
simulating the transformer finite element model based on the short circuit fault area, so as to obtain a short circuit database; and
acquiring magnetic flux leakage data between transformer windings in real time and determining a short circuit fault location of transformer windings according to the short circuit database.

2. The transformer winding short circuit fault detection method according to claim 1, wherein the acquiring magnetic flux leakage data between transformer windings specifically comprises:
evenly arranging a plurality of magnetic sensors along the axial direction of the transformer windings, so as to form a sensor group; and
measuring magnetic leakage fluxes at all locations between transformer windings according to the sensor group, so as to acquire magnetic flux leakage data between transformer windings.

3. The transformer winding short circuit fault detection method according to claim 1, after the acquiring magnetic flux leakage data between transformer windings, further comprising:
a step of pre-processing acquired magnetic flux leakage data, wherein the step of pre-processing comprises denoising, filtering, calibration and standardizing.

4. The transformer winding short circuit fault detection method according to claim 3, after the acquiring magnetic flux leakage data between transformer windings, further comprising:
carrying out mode recognition on pre-processed magnetic flux leakage data, so as to judge operation states of a transformer, wherein the operation states of the transformer comprise a normal stable operation state, an on-position state and a winding short circuit state.

5. The transformer winding short circuit fault detection method according to claim 4, wherein the determining the short circuit fault area according to the magnetic flux leakage data specifically comprises:
when determining that the operation state of the transformer is the winding short circuit state, arranging the pre-processed magnetic flux leakage data according to amplitude of variation, so as to obtain a magnetic flux leakage variation sequence table; and
determining a short circuit fault area according to the magnetic flux leakage variation sequence table.

6. The transformer winding short circuit fault detection method according to claim 5, wherein the simulating the transformer finite element model based on the short circuit fault area, so as to obtain the short circuit database specifically comprises:
setting short circuit conditions for short circuit locations in the short circuit fault area, and carrying out transient study thereon;
acquiring magnetic flux leakage traversal results of the transformer finite element model, wherein the magnetic flux leakage traversal results comprise port current waveforms, voltage waveforms and winding magnetic flux leakage data; and
establishing the short circuit database according to the port current waveforms, voltage waveforms and winding magnetic flux leakage data.

7. The transformer winding short circuit fault detection method according to claim 1, wherein the acquiring magnetic flux leakage data between transformer windings in real time and determining the short circuit fault location of transformer windings according to the short circuit database specifically comprises:
comparing the magnetic flux leakage data of the sensor with the magnetic flux leakage traversal results;
determining corresponding fault situations according to a minimum difference; and
comparing current on line side and voltage recording data at the short circuit fault with current and voltage data obtained from the finite element model, so as to determine a short circuit fault spot.

8. A transformer winding short circuit fault detection system, comprising: a magnetic flux leakage data acquiring unit, a short circuit fault determining unit, a simulation model establishing unit and a fault location determining unit,
wherein the magnetic flux leakage data acquiring unit is used for acquiring magnetic flux leakage data between transformer windings;
the short circuit fault determining unit is used for determining a short circuit fault area according to the magnetic flux leakage data;
the simulation model establishing unit is used for establishing a transformer finite element model, and simulating the transformer finite element model based on the short circuit fault area, so as to obtain a short circuit database; and
the fault location determining unit is used for acquiring magnetic flux leakage data between transformer windings in real time and determining a short circuit fault location of transformer windings according to the short circuit database.

9. A computer readable storage medium, with computer programs stored thereon, wherein the steps of the method according to claim 7 are achieved by a processor when the computer programs are executed by the processor.

10. A computer device, comprising a memory and a processor, wherein the memory is used for storing computer programs; and the steps of the method according to claim 7 are achieved when the computer programs are executed by the processor.
